(19) United States
(12) Patent Application Publication
(10) Pub. No.: US 2025/0226331 A1
(43) Pub. Date: Jul. 10, 2025

(54) BRIDGE CHIP, SEMICONDUCTOR PACKAGE INCLUDING BRIDGE CHIP AND METHOD FOR MANUFACTURING THE SAME

(71) Applicant: SAMSUNG ELECTRONICS CO., LTD., Suwon-si (KR)

(72) Inventors: Seokbeom YONG, Suwon-si (KR); Sang Sub Song, Suwon-si (KR); Seulgi Yu, Suwon-si (KR)

(73) Assignee: SAMSUNG ELECTRONICS CO., LTD., Suwon-si (KR)

(21) Appl. No.: 18/781,152

(22) Filed: Jul. 23, 2024

(30) Foreign Application Priority Data
Jan. 9, 2024 (KR) 10-2024-0003488

(51) Int. Cl. H01L 23/538; H01L 23/00; H01L 23/64; H01L 25/18; H10B 80/00

(52) U.S. Cl. CPC H01L 23/5386; H01L 23/5384; H01L 23/642; H01L 24/16; H01L 25/18; H10B 80/00; H01L 2224/16227; H01L 2224/16238; H01L 2924/1431; H01L 2924/1436

(57) ABSTRACT

A bridge chip includes a first side surface, a second side surface opposite to the first side surface in a first horizontal direction, a third side surface, a fourth side surface opposite to the third side surface in a second horizontal direction intersecting the first horizontal direction, a plurality of signal wires extending in a third horizontal direction between the first horizontal direction and the second horizontal direction, and one or more capacitor structures around the plurality of signal wires. The first ends of the plurality of signal wires are disposed in a first line along the first side surface. The second ends of the plurality of signal wires are disposed in a second line along the second side surface.

### CROSS-REFERENCE TO RELATED APPLICATIONS

This application claims benefit of priority under 35 U.S.C. § 119 to Korean Patent Application No. 10-2024-0003488, filed on Jan. 9, 2024, in the Korean Intellectual Property Office, the disclosure of which is incorporated by reference herein in its entirety.

### BACKGROUND

### 1. Field

The present disclosure relates generally to semiconductor package technology, and more particularly to a bridge chip, a semiconductor package including the bridge chip, and a method for manufacturing the same.

### 2. Description of Related Art

The semiconductor industry may be pursuing higher processing speeds, multi-functionality, and/or larger storage capacity while also attempting to reduce the size, the weight, and/or the dimensions of semiconductor packages that may be mounted on electronic devices to potentially meet increasing demands for reduced size and/or weight of the electronic devices. Thus, there exists a need for packaging technology that may provide for increased storage capabilities and/or data transmission at faster speeds. To that end, a high bandwidth memory (HBM) may have been developed to attempt to achieve a relatively high bandwidth by stacking more dynamic random access memories (DRAMs) on a substrate in the same area.

The HBM and a logic die that may be connected to the HBM may be manufactured by performing a fine process and have inputs/outputs (I/Os) having fine pitches. However, when the substrate under the HBM and the logic die has I/Os with a normal pitch, a bridge die may be needed as an intermediate medium in order to connect the HBM and the logic die to the substrate and to connect the HBM and the logic die to each other.

The bridge die may be disposed to be embedded in the substrate. Consequently, power wires on the substrate disposed near the bridge die may have a path that may bypass the area occupied by the bridge die. As a result, the power transmission path from the decoupling capacitor and the power supply line to the logic die or the HBM may be long, thus, deteriorating the power integrity (PI) characteristics of the semiconductor package.

Thus, there exists a need for further improvements in semiconductor package technology, as increasing demands for faster processing speeds, multi-functionality, and/or increased storage capacity may be constrained by deteriorating PI characteristics of the semiconductor package including the bridge die. Improvements are presented herein. These improvements may also be applicable to other semiconductor technologies.

### SUMMARY

One or more example embodiments of the present disclosure provide a semiconductor package and a method for manufacturing the semiconductor package in which, in a bridge die connecting a logic die and a high bandwidth memory (HBM) spaced apart from each other in a first horizontal direction, the bridge die includes signal wires and a capacitor structure that connect the logic die to the HBM, the signal wires extend in a third horizontal direction between the first horizontal direction and a second horizontal direction orthogonal to the first horizontal direction, and the capacitor structure is disposed in a garbage area in which the signal wires extending in the third horizontal direction may not be disposed.

According to an aspect of the present disclosure, a bridge chip includes a first side surface, a second side surface opposite to the first side surface in a first horizontal direction, a third side surface, a fourth side surface opposite to the third side surface in a second horizontal direction intersecting the first horizontal direction, a plurality of signal wires extending in a third horizontal direction between the first horizontal direction and the second horizontal direction, and one or more capacitor structures around the plurality of signal wires. The first ends of the plurality of signal wires are disposed in a first line along the first side surface. The second ends of the plurality of signal wires are disposed in a second line along the second side surface.

According to an aspect of the present disclosure, a semiconductor package includes a substrate including a cavity, a bridge die disposed within the cavity, a first semiconductor die on the substrate and the bridge die, and a second semiconductor die on the substrate and the bridge die. The bridge die includes a plurality of signal wires and one or more capacitor structures. The second semiconductor die is spaced apart from the first semiconductor die in a first horizontal direction. The plurality of signal wires electrically couple the first semiconductor die with the second semiconductor die. The plurality of signal wires extend in a third horizontal direction between the first horizontal direction and a second horizontal direction orthogonal to the first horizontal direction. The one or more capacitor structures are disposed around the plurality of signal wires.

According to an aspect of the present disclosure, a semiconductor package includes a substrate including a cavity, a bridge die disposed within the cavity, a first semiconductor die on the substrate and the bridge die, a plurality of first connection members between the bridge die and the first semiconductor die, a second semiconductor die on the substrate and the bridge die and spaced apart from the first semiconductor die in a first horizontal direction, and a plurality of second connection members between the bridge die and the second semiconductor die. The bridge die includes a plurality of signal wires and one or more capacitor structures. The plurality of first connection members are disposed in a first line along a side surface of the first semiconductor die facing the second semiconductor die. The plurality of second connection members are disposed in a second line along a side surface of the second semiconductor die facing the first semiconductor die. Each of the plurality of signal wires electrically couples a corresponding first connection member of the plurality of first connection members with a corresponding second connection member of the plurality of second connection members. The plurality of signal wires extend in a third horizontal direction between the first horizontal direction and a second horizontal direction orthogonal to the first horizontal direction. The one or more capacitor structures are disposed around the plurality of signal wires.

A capacitor structure may be disposed on a lower surface of a substrate in the form of a surface mount device (SMD), and a semiconductor package may have a long power transmission path from the capacitor structure to a logic die and a HBM. According to the present disclosure, by disposing a capacitor structure in a garbage area in which signal wires in a bridge die may not be disposed, it may be possible to reduce a power transmission path from the capacitor structure to a logic die and a HBM and potentially improve power integrity (PI) characteristics of a semiconductor package.

A power wire near an area that may be occupied by a bridge die may bypass the area occupied by the bridge die, so that a semiconductor package may have a long power transmission path. According to the present disclosure, by disposing through-silicon vias in a garbage area in which signal wires in a bridge die may not be disposed, a length of a power transmission path from a connection member of a substrate to a logic die and a HBM may potentially be reduced, and PI characteristics of a semiconductor package may potentially be improved.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 illustrates a top plan view of a semiconductor package including a bridge die, according to an embodiment;

FIG. 2 illustrates an enlarged top plan view of the bridge die of FIG. 1, according to an embodiment;

FIG. 3 illustrates a cross-sectional view of a semiconductor package including a bridge die of an embodiment taken along line A-A′ of the semiconductor package of FIG. 1, according to an embodiment;

FIG. 4 illustrates a cross-sectional view of a semiconductor package including a bridge die of an embodiment taken along line B-B′ of the semiconductor package of FIG. 1, according to an embodiment;

FIG. 5 illustrates a cross-sectional view of a semiconductor package including a bridge die of an embodiment taken along line C-C′ of the semiconductor package of FIG. 1, according to an embodiment;

FIG. 6 illustrates a top plan view of a substrate including a bridge die, according to an embodiment;

FIG. 7 illustrates an enlarged top plan view of the bridge die of FIG. 6, according to an embodiment;

FIG. 8 illustrates a cross-sectional view of a semiconductor package including a bridge die of an embodiment taken along line A-A′ of the semiconductor package of FIG. 6, according to an embodiment;

FIG. 9 illustrates a cross-sectional view of a semiconductor package including a bridge die of an embodiment taken along line B-B′ of the semiconductor package of FIG. 6, according to an embodiment;

FIG. 10 illustrates a cross-sectional view of a semiconductor package including a bridge die of an embodiment taken along line C-C′ of the semiconductor package of FIG. 6, according to an embodiment; and

FIG. 11 to FIG. 21 illustrate cross-sectional views of a method for manufacturing a semiconductor package, according to an embodiment.

### DETAILED DESCRIPTION

The present disclosure is described more fully hereinafter with reference to the accompanying drawings, in which embodiments of the present disclosure are shown. As those skilled in the art may recognize, the described embodiments may be modified in various different ways, all without departing from the spirit or scope of the present disclosure.

In order to clearly describe the present disclosure, parts that are irrelevant to the description may be omitted, and identical or similar constituent elements throughout the specification may be denoted by the same reference numerals.

Further, in the drawings, the size and thickness of each element are arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element. In addition, unless explicitly described to the contrary, the word “comprise” and variations such as “comprises” or “comprising” are to be understood to imply the inclusion of stated elements but not the exclusion of any other elements.

It is to be understood that when an element such as a layer, film, region, area, or substrate is referred to as being “on” or “above” another element, the element may be directly on the other element or intervening elements may also be present. Alternatively, when an element is referred to as being “directly on” another element, there may be no intervening elements present. Further, in the specification, the word “on” or “above” may refer to an element disposed on or below the object portion, and may not necessarily indicate that the element is disposed on the upper side of the object portion based on a gravitational direction.

Further, throughout the specification, the phrase “in a plan view” or “on a plane” may refer to viewing a target portion from the top, and the phrase “in a cross-sectional view” or “on a cross-section” may refer to viewing a cross-section formed by vertically cutting a target portion from the side.

It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “AlO”, “SiO”, and the like may refer to a material made of elements included in each of the terms and is not a chemical formula representing a stoichiometric relationship.

Hereinafter, a semiconductor package and a method for manufacturing the semiconductor package, according to various embodiments, are described with reference to the accompanying drawings.

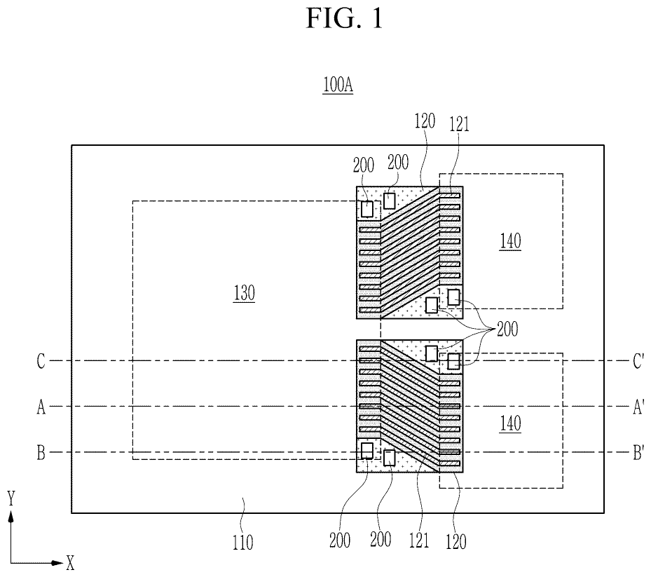

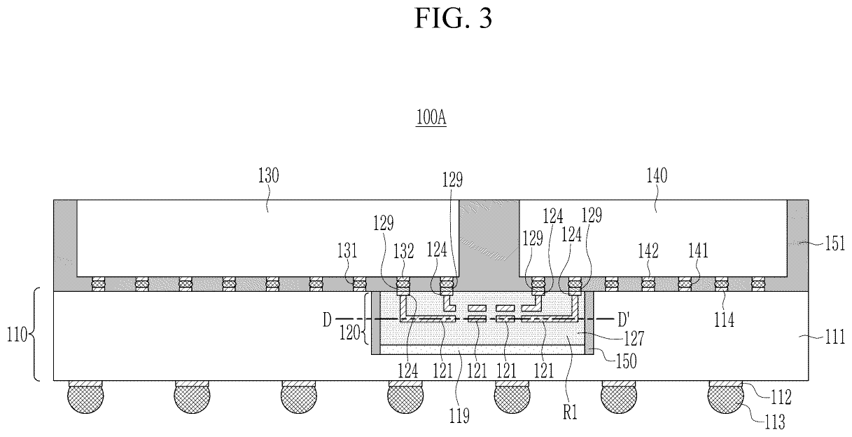

FIG. 1 illustrates a top plan view of a semiconductor package 100A including a bridge die 120, according to an embodiment. FIG. 1 illustrates a top plan view taken along line D-D′ of the semiconductor package 100A of FIGS. 3 to 5.

Referring to FIG. 1, the semiconductor package 100A may include a substrate 110, bridge dies (e.g., bridge chips) 120, a logic die 130, and high bandwidth memories (HBM) 140. For ease of description, with reference to FIG. 1, the substrate 110 and the bridge dies 120 are shown by solid lines, and the logic die 130 and the HBM 140 are shown by dotted lines.

The logic die 130 (e.g., a first semiconductor die 130) and the HBM 140 (e.g., a second semiconductor die) may be disposed on the substrate 110. The HBM 140 may be disposed next (e.g., adjacent) to the logic die 130. The HBM 140 may be spaced apart from the logic die 130 in an X direction (e.g., a first horizontal direction; −X direction may also be referred to as the first horizontal direction). One of the HBM 140 may be spaced apart from the other HBM 140 in a Y direction (e.g., a second horizontal direction; −Y direction may also be referred to as the second horizontal direction). Each of the HBM 140 may have one side surface protruding from one side surface of the logic die 130 in the Y direction (a direction intersecting or orthogonal to the X direction, for example, the second horizontal direction). Each of the HBM 140 may have one side surface protruding from one side surface of the corresponding bridge die 120 in the Y direction (e.g., second horizontal direction). In another embodiment, one HBM 140 may be disposed next (e.g., adjacent) to the logic die 130.

The bridge dies 120 may be disposed in a cavity of the substrate 110. Each of the bridge dies 120 may be disposed under the logic die 130 and each of the HBM 140. Each of the bridge dies 120 may electrically connect the logic die 130 and the HBM 140. One of the bridge dies 120 may be spaced apart from the other bridge dies 120 in the Y direction (e.g., second horizontal direction). Each of the bridge dies 120 may have one side surface protruding from one side surface of the logic die 130 in the Y direction (e.g., second horizontal direction). In another embodiment, the number of bridge dies 120 may be one (1). The arrangement of the bridge die 120, the logic die 130, and the HBM 140 may have an offset in the Y direction (e.g., second horizontal direction).

The footprint of the logic die 130 and the footprint of the HBM 140 may not overlap each other. The footprint of each of the bridge dies 120 may overlap the footprint of the logic die 130 and the footprint of a corresponding HBM 140 of the HBM 140. One of the corners of the footprint of the logic die 130 may overlap the footprint of the bridge die 120, and one of the corners of the footprint of the bridge die 120 may overlap the footprint of the logic die 130. One of the corners of the footprint of the HBM 140 may overlap the footprint of the bridge die 120, and one of the corners of the footprint of the bridge die 120 may overlap the footprint of the HBM 140.

The bridge die 120 may include signal wires 121 and one or more capacitor structures 200. The signal wires 121 may electrically connect the logic die 130 to the HBM 140. When the structure in which the arrangement of the bridge die 120, the logic die 130, and the HBM 140 has an offset in the Y direction (e.g., second horizontal direction), the signal wires 121 electrically connecting the logic die 130 and the HBM 140 may extend in a third horizontal direction between the X direction (e.g., first horizontal direction) and the Y direction (e.g., second horizontal direction). One or more capacitor structures 200 may be disposed around the signal wires 121.

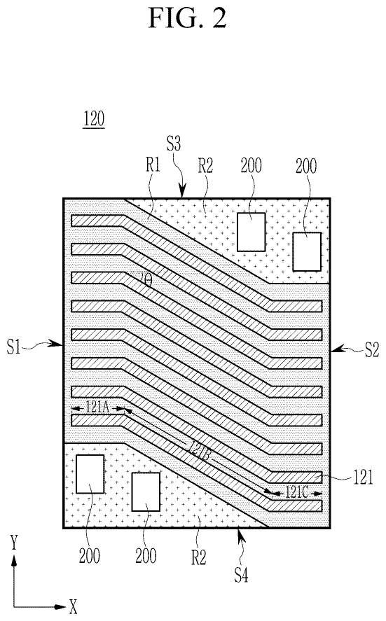

FIG. 2 illustrates an enlarged top plan view of the bridge die 120 of FIG. 1, according to an embodiment.

Referring to FIG. 2, the bridge die 120 may include a first side surface S1 and a second side surface S2 opposite to each other in the X direction (e.g., first horizontal direction), and a third side surface S3 and a fourth side surface S4 opposite to each other in the Y direction (e.g., second horizontal direction). The first side surface S1 may be a surface facing the logic die 130. The second side surface S1 may be a surface facing the HBM 140. The third side surface S3 may be a surface facing the other bridge die 120. The fourth side surface S4 may be a surface opposite to the third side surface S3.

In an embodiment, first ends of the signal wires 121 may be arranged in a line along the first side surface S1. Alternatively or additionally, second ends of the signal wires 121 may be arranged in a line along the second side surface S2. The signal wires 121 may extend from the first side surface S1 to the second side surface S2. The signal wires 121 may extend in the third horizontal direction between the X direction (e.g., first horizontal direction) and the Y direction (e.g., second horizontal direction). In an embodiment, the angle θ between the third horizontal direction and the X direction (e.g., first horizontal direction) may be 45 degrees. However, the present disclosure is not limited in this regard. That is, the angle θ between the third horizontal direction and the X direction may include other values. In an embodiment, each of the signal wires 121 may include a first portion 121A connected to a first connection member 131 and connected to the logic die 130 (as shown in FIG. 3) and extending in the X direction (e.g., first horizontal direction), a second portion 121B extending in the third horizontal direction following the first portion 121A, and a third portion 121C extending in the X direction (e.g., first horizontal direction) following the second portion 121B and connected to the second connection member connected to the HBM. In another embodiment, the signal wires 121 may extend only in the third horizontal direction without the first portion 121A and the third portion 121C.

The bridge die 120 may include a first area R1 and a second area R2 that may be defined by dividing a plane of the bridge die 120. The first area R1 may refer to an area in which the signal wires 121 are disposed, and the second area R2 may refer to a garbage area in which the signal wires 121 extending in the third horizontal direction may not be disposed. When the signal wires 121 extend in the third horizontal direction, a garbage area in which the signal wires 121 may not be disposed in the bridge die 120 including side surfaces extending in the X direction (e.g., first horizontal direction) and the Y direction (e.g., second horizontal direction) may be formed. One or more capacitor structures 200 may be disposed in a garbage area in which the signal wires 121 in the bridge die 120 may not be disposed to potentially reduce the length of the power transmission path from the capacitor structure 200 to the logic die 130 and the HBM 140, and potentially improve the power integrity (PI) characteristics of the semiconductor package 100A.

FIG. 3 illustrates a cross-sectional view of the semiconductor package 100A including the bridge die 120 of the embodiment taken along line A-A′ of the semiconductor package 100A of FIG. 1, according to an embodiment.

Referring to FIG. 3, the semiconductor package 100A may include the substrate 110, the bridge dies (bridge chips) 120, a first molding material 150, the logic die 130, first connection members 131, the HBM 140, second connection members 141, and a second molding material 151. In an embodiment, the semiconductor package 100 may be manufactured based on fan out wafer level package (FOWLP) and/or fan out panel level package (FOPLP) technology.

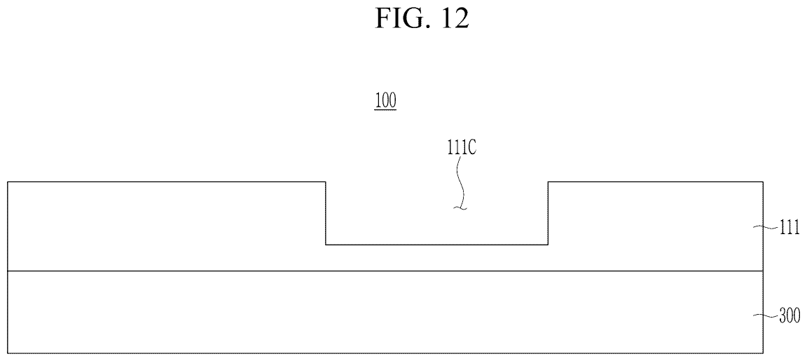

The substrate 110 may include a substrate die base 111 including one or more cavities (e.g., cavities 111C of FIG. 12), a connection pad 112, a connection member 113, and a first bonding pad 114. In an embodiment, the substrate 110 may include a printed circuit board (PCB), a redistribution layer (RDL) structure, or an interposer. In an embodiment, the interposer may include, but not be limited to, an organic interposer, a silicon interposer, or a composite interposer. In another embodiment, a substrate 110 including fewer or more bonding pads, connection pads, and connection members may be included within the scope of the present disclosure.

The substrate die base 111 may include a dielectric, vias, and/or wiring lines. The dielectric may be configured to protect and/or insulate the vias and the wire lines. The first bonding pads 114 may be disposed on the upper surface of the dielectric. The connection pads 112 may be disposed on the lower surface of the dielectric. Each of the vias and each of the wire lines may be disposed between the connection pad 112 and the first bonding pad 114. Each of the vias and each of the wiring lines may electrically connect the first bonding pad 114 to the connection pad 112. The substrate die base 111 may include one or more cavities 111C for disposing one or more bridge dies 120. In an embodiment, the dielectric may include a photo imageable dielectric (PID). In an embodiment, the dielectric may include, but not be limited to, silicon (Si) or a silicon oxide (SiO). In an embodiment, the dielectric may include a thermosetting resin such as, but not limited to, an epoxy resin, a thermoplastic resin such as polyimide, or a material in which these resins are mixed with an inorganic filler. In an embodiment, the dielectric may include prepreg, Ajinomoto Build-up Film (ABF), FR-4, and Bismaleimide Triazine (BT). In an embodiment, each of the via and the wiring line may include, but not be limited to, at least one of copper (Cu), aluminum (Al), tungsten (W), nickel (Ni), gold (Au), tin (Sn), titanium (Ti), or an alloy thereof.

The first bonding pads 114 may be disposed on the upper surface of the substrate die base 111. Each of the first bonding pads 114 may be disposed between the via of the substrate die base 111 and the first connection member 131 connected to the logic die 130, and/or between the via of the substrate die base 111 and the second connection member 141 connected to the HBM 140. Each of the first bonding pads 114 may electrically connect the first connection member 131 connected to the logic die 130 to the via of the substrate die base 111 and/or the second connection member 141 connected to the HBM 140 to the via of the substrate die base 111. In an embodiment, the first bonding pad 114 may include, but not be limited to, at least one of copper (Cu), nickel (Ni), zinc, gold (Au), silver (Ag), platinum (Pt), palladium (Pd), chromium (Cr), titanium (Ti), or an alloy thereof.

The connection pads 112 may be disposed on the lower surface of the substrate die base 111. Each of the connection pads 112 may be disposed between the via of the substrate die base 111 and the connection member 113. Each of the connection pads 112 may electrically connect the via of the substrate die base 111 to the connection member 113. Each of the connection members 113 may be disposed below each of the connection pads 112. The connection members 113 may electrically connect the semiconductor package 100A to an external device. In an embodiment, the connection pad 112 may include, but not be limited to, at least one of copper (Cu), nickel (Ni), zinc, gold (Au), silver (Ag), platinum (Pt), palladium (Pd), chromium (Cr), titanium (Ti), or an alloy thereof. In an embodiment, the connection member 113 may include a micro bump or a solder ball. In an embodiment, the connection member 113 may include, but not be limited to, at least one of tin (Sn), silver (Ag), lead (Pb), nickel (Ni), copper (Cu), and an alloy thereof.

The bridge die 120 may be disposed in the cavity 111C of the substrate 110. The bridge die 120 may be attached to the cavity 111C of the substrate 110 by an adhesive member 119. The adhesive member 119 may be attached to the bottom surface of the cavity 111C of the substrate 110, and the bridge die 120 may be attached to the adhesive member 119. In an embodiment, the adhesive member 119 may include, but not be limited to, a die attach film (DAF) 119. The bridge die 120 may include a bridge die base 127, and signal wires 121 and upper connection pads 124 within the bridge die base 127. Referring to FIG. 3, a cross-section of the first area R1 of the bridge die 120 is shown. The capacitor structure 200 may not be disposed in the first area R1. In an embodiment, the bridge die 120 may include a silicon bridge die. The DAF 119 may be disposed on the lower surface of the bridge die base 127. The side surfaces of the bridge die base 127 may be surrounded by the first molding material 150. The upper surface of the bridge die base 127 may be surrounded by the second molding material 151. In an embodiment, the bridge die base 127 may include, but not be limited to, silicon (Si). In an embodiment, the bridge die base 127 may be made of a wafer and may include the same material as the wafer.

Each of the signal wires 121 may be disposed between the upper connection pad 124 connected to the logic die 130 and the upper connection pad 124 connected to the HBM 140. Each of the signal wires 121 may electrically connect the upper connection pad 124 connected to the logic die 130 to the upper connection pad 124 connected to the HBM 140. In an embodiment, the signal wires 121 may include, but not be limited to, at least one of copper (Cu), aluminum (Al), silver (Ag), tin (Sn), gold (Au), nickel (Ni), lead (Pb), titanium (Ti), tungsten (W), or an alloy thereof.

Each of the upper connection pads 124 may be disposed between the second bonding pad 129 connected to the first connection member 131 and the signal wire 121, and/or between the second bonding pad 129 connected to the second connection member 141 and the signal wire 121. Each of the upper connection pads 124 may electrically connect the second bonding pad 129 connected to the first connection member 131 to the signal wire 121 and/or the second bonding pad 129 connected to the second connection member 141 to the signal wire 121. In an embodiment, the upper connection pad 124 may include, but not be limited to, at least one of copper (Cu), aluminum (Al), silver (Ag), tin (Sn), gold (Au), nickel (Ni), lead (Pb), titanium (Ti), or an alloy thereof.

The second bonding pads 129 are disposed on the upper surface of the bridge die base 127. Each of the second bonding pads 129 is disposed between the upper connection pad 124 and the first connection member 131 connected to the logic die 130, or between the upper connection pad 124 and the second connection member 141 connected to the HBM 140. Each of the second bonding pads 129 electrically connects the first connection member 131 connected to the logic die 130 to the upper connection pad 124 or the second connection member 141 connected to the HBM 140 to the upper connection pad 124. In an embodiment, the first bonding pad 114 may include at least one of copper (Cu), nickel (Ni), zinc, gold (Au), silver (Ag), platinum (Pt), palladium (Pd), chromium (Cr), titanium (Ti), and an alloy thereof.

The first molding member 150 may cover the bridge die 120 and the adhesive member 119 within the cavity 111C of the substrate 110. The first molding material 150 may protect the bridge die 120 from an external environment, and thus, the bridge die 120 may be provided with electrical and/or mechanical stability.

The logic die 130 may be disposed on the substrate 110 and the bridge die 120. The logic die 130 may be electrically connected to the HBM 140 by the signal wires 121 of the bridge die 120. In an embodiment, the logic die 130 may be and/or may include a system on chip (SoC). In an embodiment, the logic die 130 may include an application processor (AP). In an embodiment, the logic die 130 may include at least one of a central processing unit (CPU) or a graphics processing unit (GPU). The logic die 130 may include first connection pads 132. Each of the first connection pads 132 may be disposed on the first connection member 131 and may be electrically connected to the first connection member 131. In an embodiment, the first connection pad 132 may include, but not be limited to, at least one of copper (Cu), nickel (Ni), zinc, gold (Au), silver (Ag), platinum (Pt), palladium (Pd), chromium (Cr), titanium (Ti), or an alloy thereof.

Each of the first connection members 131 may be disposed between the first bonding pad 114 of the substrate 110 and the first connection pad 132 of the logic die 130, and/or between the second bonding pad 129 of the bridge die 120 and the first connection pad 132 of the logic die 130. Each of the first connection members 131 may electrically connect the first connection pad 132 of the logic die 130 to the first bonding pad 114 of the substrate 110 and/or the first connection pad 132 of the logic die 130 to the second bonding pad 129 of the bridge die 120. Among the first connection members 131, the first connection members 131 connected to the signal wires 121 of the bridge die 120 may be arranged in a line along the side surface of the logic die 130 facing the HBM 140. In an embodiment, the first connection member 131 may include a micro bump or a solder ball. In an embodiment, the first connection member 131 may include, but not be limited to, at least one of tin (Sn), silver (Ag), lead (Pb), nickel (Ni), copper (Cu), or an alloy thereof.

The HBM 140 may be disposed on the substrate 110 and bridge die 120. The HBM 140 may be electrically connected to the logic die 130 by the signal wires 121 of the bridge die 120. The HBM 140 may be disposed side by side with the logic die 130. In an embodiment, the HBM 140 may be plural (e.g., include two or more HBMs 140) and may be disposed next to one side surface and/or both side surfaces of the logic die 130. The HBM 140 may be and/or may include a high-performance three-dimensional (3D) stacked dynamic random access memory (DRAM). The HBM 140 may be manufactured by performing hybrid bonding and/or vertically stacking of memory dies on a buffer chip using micro-bumps to form one memory stack. The HBM 140 may include second connection pads 142. Each of the second connection pads 142 may be disposed on the second connection member 141 and may be electrically connected to the second connection member 141. In an embodiment, the second connection pad 142 may include, but not be limited to, at least one of copper (Cu), nickel (Ni), zinc, gold (Au), silver (Ag), platinum (Pt), palladium (Pd), chromium (Cr), titanium (Ti), or an alloy thereof.

Each of the second connection members 141 may be disposed between the first bonding pad 114 of the substrate 110 and the second connection pad 142 of the HBM 140, and/or between the second bonding pad 129 of the bridge die 120 and the second connection pad 142 of the HBM 140. Each of the second connection members 141 may electrically connect the second connection pad 142 of the HBM 140 to the first bonding pad 114 of the substrate 110 and/or the second connection pad 142 of the HBM 140 to the second bonding pad 129 of the bridge die 120. Among the second connection members 141, the second connection members 141 connected to the signal wires 121 of the bridge die 120 may be arranged in a line along the side surface of the HBM 140 facing the logic die 130. Among the second connection members 141, the second connection members 141 connected to the signal wires 121 of the bridge die 120 may be arranged with an offset in the Y direction (e.g., second horizontal direction) with the first connection members 131 connected to the signal wires 121 of the bridge die 120 from among the first connection members 131. In an embodiment, the second connection member 141 may include a micro bump or a solder ball. In an embodiment, the second connection member 141 may include, but not be limited to, at least one of tin (Sn), silver (Ag), lead (Pb), nickel (Ni), copper (Cu), and an alloy thereof.

The second molding material 151 may cover the logic die 130, the first connection members 131, the HBM 140, and the second connection members 141 on the substrate 110, the bridge die 120, and the first molding material 150. The second molding material 151 may protect the logic die 130, the first connection members 131, the HBM 140, and the second connection members 141 from an external environment, thereby potentially providing electrical and/or mechanical stability to the semiconductor package 100A.

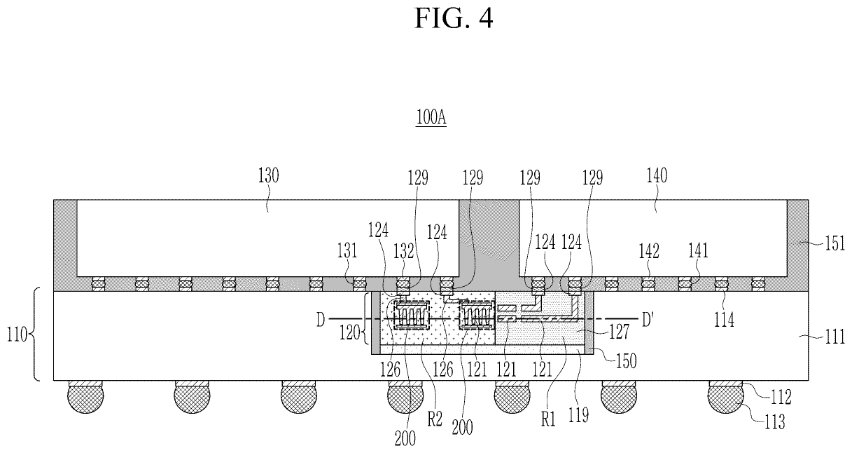

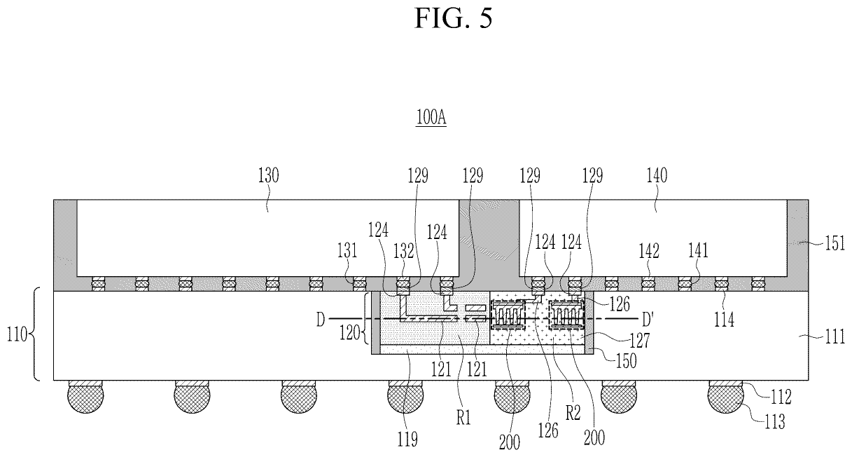

FIG. 4 illustrates a cross-sectional view of the semiconductor package 100A including the bridge die 120 of the embodiment taken along line B-B′ of the semiconductor package 100A of FIG. 1, according to an embodiment. FIG. 5 illustrates a cross-sectional view of the semiconductor package 100A including the bridge die 120 of the embodiment taken along line C-C′ of the semiconductor package 100A of FIG. 1, according to an embodiment.

Referring to FIGS. 4 and 5, cross-sections of the first area R1 and the second area R2 of the bridge die 120 are shown. As shown in FIGS. 4 and 5, the bridge die 120 may include a bridge die base 127, signal wires 121, one or more capacitor structures 200, contact plugs 126, and upper connection pads 124 within the bridge die base 127. The signal wires 121 may be disposed in the first area R1. One or more capacitor structures 200 may be disposed in the second area R2.

One or more capacitor structures 200 may be connected to the contact plug 126. That is, the capacitor structure 200 may serve as a decoupling capacitor. In an embodiment, the capacitor structure 200 may be and/or may include an integrated stack capacitor (ISC) structure. The ISC structure may have a horizontal and/or vertical 3D capacitor structure in which a capacitor may be formed in a vertical direction along an inner surface of each of through holes and a capacitor may be formed in a vertical direction that continuously extends along through holes arranged in a horizontal direction

Accordingly, the ISC structure may have an increased capacitance (e.g., ten (10) times or more) when compared to related capacitors. In another embodiment, the capacitor structure 200 may be and/or may include a metal-insulator-metal (MIM) capacitor or a deep trench capacitor (DTC).

In related semiconductor packages, the capacitor may be disposed on the lower surface of the substrate in the form of a surface mount device (SMD), and consequently, the related semiconductor package may have a relatively long power transmission path from the SMD to the logic die and/or the HBM. Aspects of the present disclosure may provide for the capacitor structure 200 to be disposed in the garbage area (e.g., second area R2) in which the signal wires 121 in the bridge die 120 may not be disposed, so that power from the capacitor structure 200 may be directly transmitted to the logic die 130 and/or the HBM 140 without passing through the substrate 110. Accordingly, the length of the power transmission path from the capacitor structure 200 to the logic die 130 and/or the HBM 140 may be potentially reduced, and the PI characteristics of the semiconductor package may be potentially improved.

The contact plug 126 in the first area R1 may be disposed between the capacitor structure 200 and the upper connection pad 124. The contact plug 126 in the first area R1 may connect the upper connection pad 124 to the capacitor structure 200. In an embodiment, the contact plug 126 may include, but not be limited to, at least one of copper (Cu), aluminum (Al), tungsten (W), nickel (Ni), gold (Au), tin (Sn), titanium (Ti), or an alloy thereof.

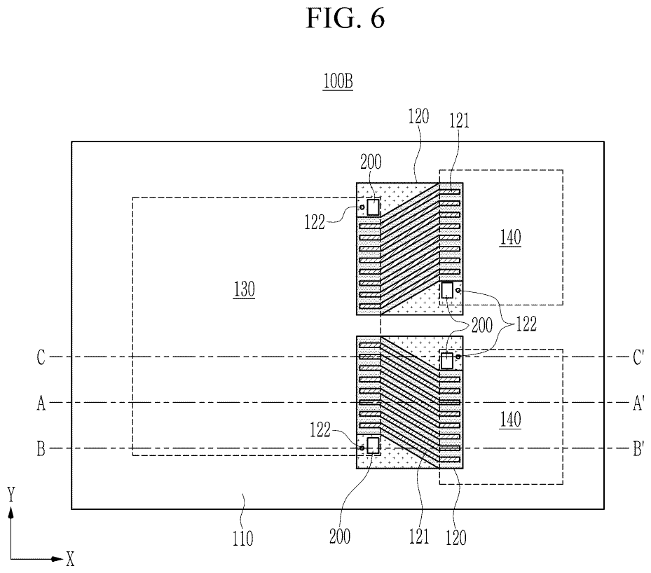

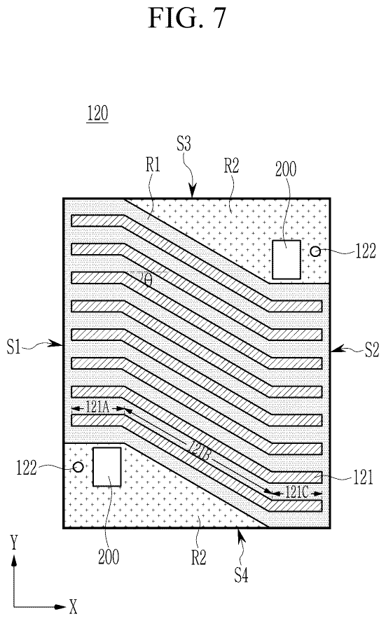

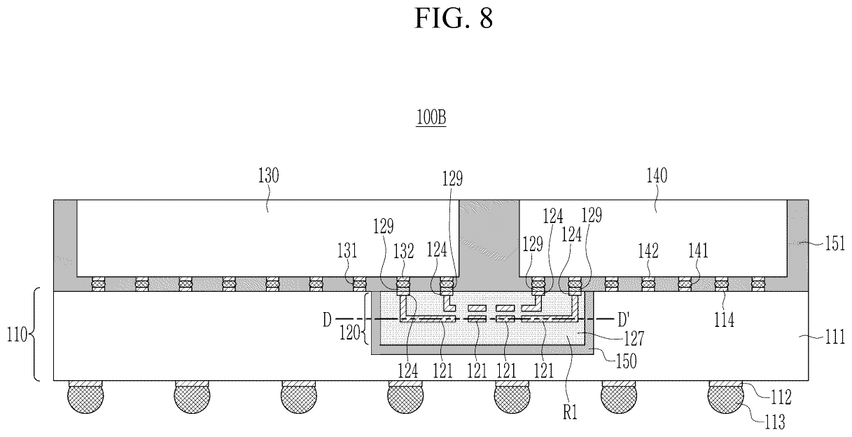

FIG. 6 illustrates a top plan view of a semiconductor package 100B including the bridge die 120, according to the embodiment. FIG. 1 illustrates a top plan view taken along line D-D′ of the semiconductor package 100A of FIGS. 8 to 10. FIG. 7 illustrates an enlarged top plan view of the bridge die 120 of FIG. 6, according to the embodiment.

Referring to FIGS. 6 and 7, the bridge die 120 may include signal wires 121, one or more capacitor structures 200, and one or more through silicon vias 122. The bridge die 120 may include the first area R1 and the second area R2 that may be defined by dividing a plane of the bridge die 120. The first area R1 may refer to an area in which the signal wires 121 are disposed, and the second area R2 may be referred to as a garbage area in which the signal wires 121 extending in the third horizontal direction may not be disposed. One or more through silicon vias 122 may be disposed in a garbage area in which the signal wires 121 in the bridge die 120 may not be disposed to potentially reduce the length of the power transmission path from the connection member 113 of the substrate 110 to the logic die 130 and the HBM 140, and potentially improve the PI characteristics of the semiconductor package 100B.

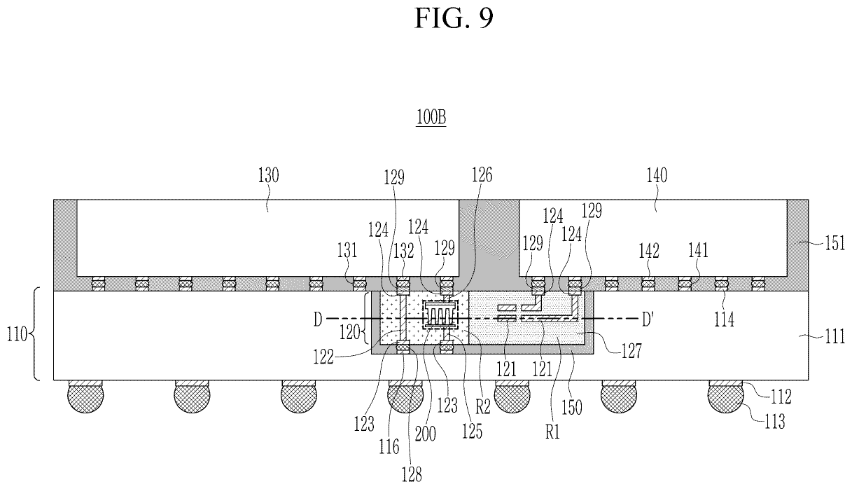

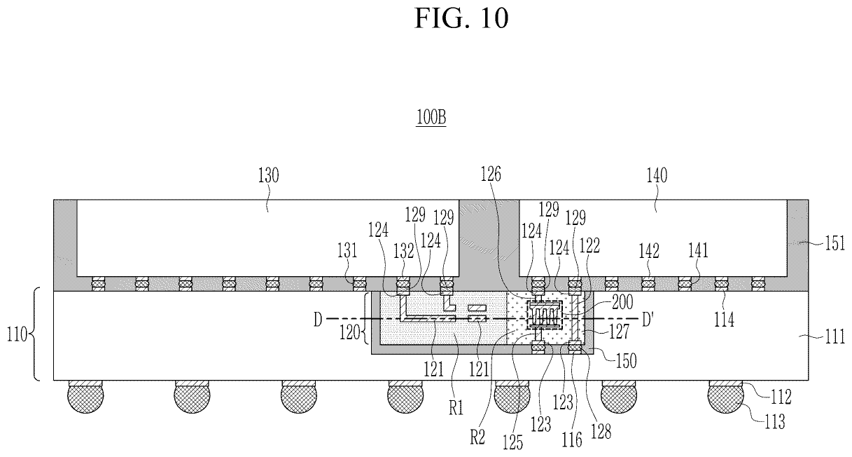

FIG. 8 illustrates a cross-sectional view of the semiconductor package 100B including the bridge die 120 of the embodiment taken along line A-A′ of the semiconductor package 100B of FIG. 6, according to an embodiment. FIG. 9 illustrates a cross-sectional view of the semiconductor package 100B including the bridge die 120 of the embodiment taken along line B-B′ of the semiconductor package 100B of FIG. 6, according to an embodiment. FIG. 10 illustrates a cross-sectional view of the semiconductor package 100B including the bridge die 120 of the embodiment taken along line C-C′ of the semiconductor package 100A of FIG. 1, according to an embodiment.

Referring to FIGS. 8 to 10, the substrate 110 may include third bonding pads 116 within the cavity 111C. The third bonding pads 116 may be disposed on the bottom surface of the cavity 111C. Each of the third bonding pads 116 may be disposed between the via of the substrate die base 111 and the third connection member 128 connected to the bridge die 120. Each of the third bonding pads 116 may electrically connect the third connection member 128 connected to the bridge die 120 to the via of the substrate die base 111. In an embodiment, the third bonding pad 116 may include, but not be limited to, at least one of copper (Cu), nickel (Ni), zinc, gold (Au), silver (Ag), platinum (Pt), palladium (Pd), chromium (Cr), titanium (Ti), or an alloy thereof.

The bridge die 120 may be disposed in the cavity 111C of the substrate 110. Using a flip chip bonding method, the bridge die 120 may be mounted within the cavity 111C of the substrate 110 by the third connection member 128. The bridge die 120 may include a bridge die base 127, signal wires 121, one or more through silicon vias 122, one or more capacitor structures 200, lower connection pads 123, and upper connection pads 124 within the bridge die base 127. In FIG. 8, a cross-section of the first area R1 of the bridge die 120 is shown. The capacitor structure 200 and the through silicon via 122 may not be disposed in the first area R1. In FIG. 9 and FIG. 10, cross-sections of the first area R1 and the second area R2 of the bridge die 120 are shown. The signal wires 121 may be disposed in the first area R1. In the second area R2, one or more capacitor structures 200 and one or more through silicon vias 122 may be disposed.

The third connection member 128 and the first molding material 150 may be disposed on the lower surface of the bridge die base 127. The side surfaces of the bridge die base 127 may be surrounded by the first molding material 150. The upper surface of the bridge die base 127 may be surrounded by the second molding material 151.

Each of the lower connection pads 123 may be disposed between the third connection member 128 and the through silicon via 122, and/or between the third connection member 128 and the contact plug 125. Each of the lower connection pads 123 may electrically connect the through silicon via 122 to the third connection member 128 and/or the contact plug 125 to the third connection member 128. In an embodiment, the lower connection pad 123 may include, but not be limited to, at least one of copper (Cu), aluminum (Al), silver (Ag), tin (Sn), gold (Au), nickel (Ni), lead (Pb), titanium (Ti), or an alloy thereof.

One or more through silicon vias 122 may electrically connect at least one of the logic die 130 and the HBM 140 to the substrate 110. One or more through silicon vias 122 may be electrically connected to the corresponding (e.g., neighboring) capacitor structure 200 from among the one or more capacitor structures 200. One or more through silicon vias 122 may be configured to transmit power. Each of the one or more through silicon vias 122 may be disposed between the lower connection pad 123 and the upper connection pad 124. Each of the one or more through silicon vias 122 may electrically connect the upper connection pad 124 to the lower connection pad 123. One or more through silicon vias 122 may penetrate the bridge die base 127.

In a related semiconductor package, a power wire in a substrate that is disposed near an area occupied by a bridge die may need to bypass the area occupied by the bridge die, and as a result, the related semiconductor package may have a relatively long power transmission path from a connection member (e.g., solder ball) of a substrate to a logic die or a HBM. Aspects of the present disclosure may provide for disposing one or more through silicon vias 122 in the garbage area (e.g., second area R2) in the bridge die 120 in which the signal wires 121 of the bridge die 120 may not be disposed, and as a result, the length of the power transmission path from the connection member (e.g., solder ball) of the substrate to the logic die 130 and the HBM 140 may be reduced, and/or the PI characteristics of the semiconductor package 100B may be potentially improved, when compared to the related semiconductor package.

One or more capacitor structures 200 may be disposed between the contact plug 125 and the contact plug 126. One or more capacitor structures 200 may electrically connect the contact plug 126 to the contact plug 125.

Each of the upper connection pads 124 may be disposed between the second bonding pad 129 and the through silicon via 122, between the second bonding pad 129 and the contact plug 126, and/or between the second bonding pad 129 and the signal wire 121. Each of the upper connection pads 124 may electrically connect the second bonding pad 129 to the through silicon via 122, the second bonding pad 129 to the contact plug 126, and/or the second bonding pad 129 to the signal wire 121. In an embodiment, the upper connection pad 124 may include, but not be limited to, at least one of copper (Cu), aluminum (Al), silver (Ag), tin (Sn), gold (Au), nickel (Ni), lead (Pb), titanium (Ti), and an alloy thereof.

The third connection members 128 may be disposed between the bridge die base 127 and the bottom surface of the cavity 111C of the substrate 110. Each of the third connection members 128 may be disposed between the third bonding pad 116 and the lower connection pad 123. Each of the third connection members 128 may electrically connect the lower connection pad 123 to the third bonding pad 116. In an embodiment, the third connection member 128 may include a micro bump or a solder ball. In an embodiment, the third connection member 128 may include, but not be limited to, at least one of tin (Sn), silver (Ag), lead (Pb), nickel (Ni), copper (Cu), and an alloy thereof.

The descriptions of FIGS. 1 to 5 may be applied to features of configurations other than those described above with respect to FIGS. 6 to 10.

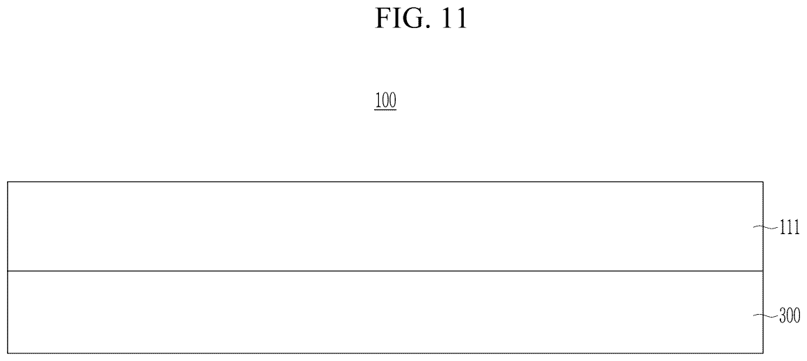

FIG. 11 to FIG. 21 illustrate cross-sectional views of a method for manufacturing the semiconductor package (e.g., semiconductor package 100A or 100B), according to the embodiment.

FIG. 11 illustrates a cross-sectional view of an operation of forming the substrate die base 111 on a carrier 300, according to an embodiment.

Referring to FIG. 11, the substrate die base 111 may formed on the carrier 300. In an embodiment, the substrate die base 111 may be manufactured by performing a process of forming a dielectric and wires on the carrier 300. In an embodiment, a pre-manufactured substrate die base 111 may be attached onto the carrier 300. In an embodiment, the pre-manufactured substrate die base 111 may be attached onto the carrier 300 by a laser or an adhesive member. In an embodiment, the carrier 300 may include, but not be limited to, a silicon-based material such as glass or a silicon oxide (SiO), an organic material, or another material such as an aluminum oxide (AlO), a combination of these materials, and/or the like.

FIG. 12 illustrates a cross-sectional view of an operation of forming the cavity 111C in the substrate die base 111, according to an embodiment.

Referring to FIG. 12, the cavity 111C may be formed in the substrate die base 111. A photoresist may be applied on the substrate die base 111, and the photoresist may be selectively exposed and developed to form a photoresist pattern. An etching process using the photoresist pattern as a mask may be performed to form the cavity 111C within the substrate die base 111.

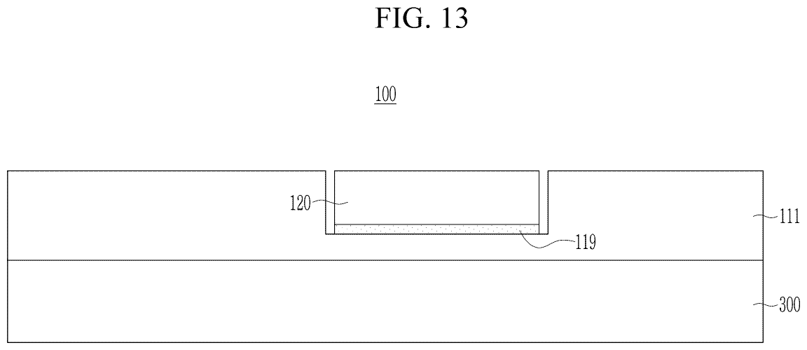

FIG. 13 illustrates a cross-sectional view of an operation of bonding the bridge die base 127 to the cavity 111C of the substrate die base 111, according to an embodiment.

Referring to FIG. 13, the bridge die base 127 may be bonded to the cavity 111C of the substrate die base 111. In an embodiment of the semiconductor package 100A, the bridge die 120 may be attached to the bottom surface of the cavity 111C by the adhesive member 119. In an embodiment of the semiconductor package 100B, the bridge die base 127 may be bonded onto the third bonding pads 116 on the bottom surface of the cavity 111C by using the third connection members 128 (e.g., performing a flip chip bonding process).

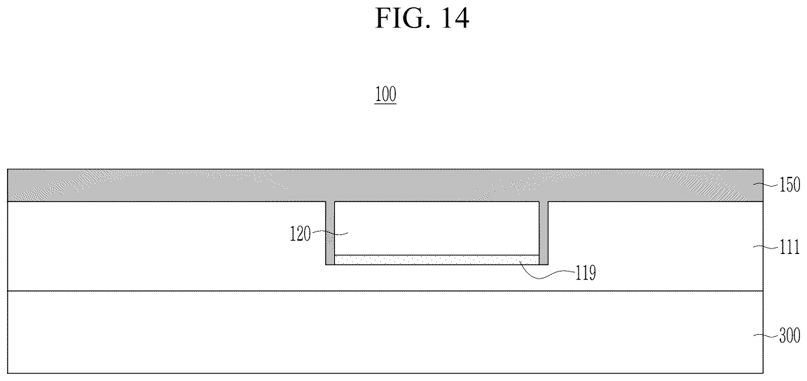

FIG. 14 illustrates a cross-sectional view of an operation of covering the bridge die base 127 with the first molding material 150 within the cavity 111C of the substrate die base 111, according to an embodiment.

Referring to FIG. 14, the bridge die 120 may be covered with the first molding material 150 within the cavity 111C of the substrate die base 111. In an embodiment, the process of molding with the first molding material 150 may include a compression molding and/or a transfer molding process. In an embodiment, the molding material 150 may include, but not be limited to, an epoxy molding compound (EMC).

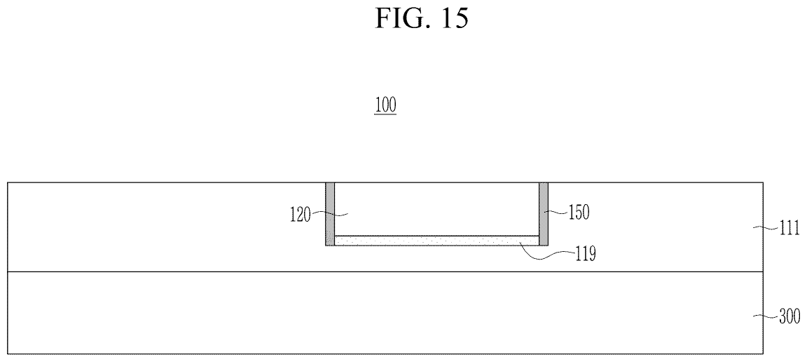

FIG. 15 illustrates a cross-sectional view of an operation of planarizing the first molding material 150, according to an embodiment.

Referring to FIG. 15, chemical mechanical polishing (CMP) may be performed to level the upper surface of the first molding material 150. The upper surface of the first molding material 150 may be planarized by applying the CMP process. After performing the CMP process, the upper surfaces of the substrate die base 111, the bridge die base 127, and the first molding material 150 may be exposed.

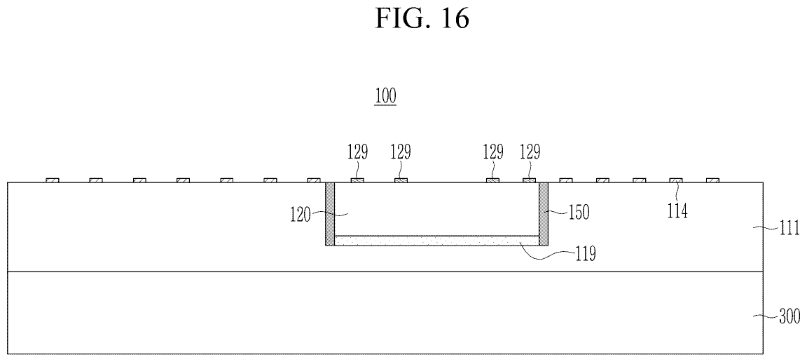

FIG. 16 illustrates a cross-sectional view of an operation of forming the first bonding pads 114 on the substrate die base 111 and forming the second bonding pads 129 on the bridge die 120, according to an embodiment.

Referring to FIG. 16, the first bonding pads 114 may be formed on the substrate die base 111, and the second bonding pads 129 may be formed on the bridge die base 127. A photoresist may be applied on the substrate die base 111, the bridge die base 127, and the first molding material 150, and the photoresist may be selectively exposed and developed to form a photoresist pattern. Thereafter, a seed metal layer may be formed on the photoresist pattern and an electroplating process may be performed to form the first bonding pads 114 and the second bonding pads 129.

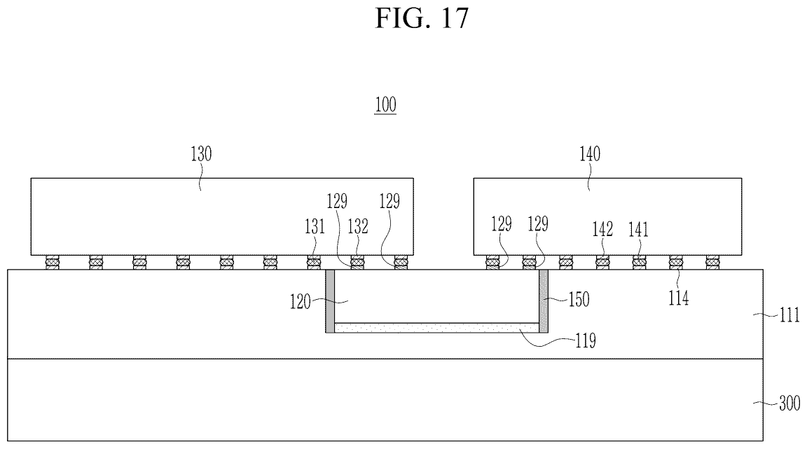

FIG. 17 illustrates a cross-sectional view of an operation of mounting the logic die 130 and the HBM 140 on the substrate 110 and the bridge die 120, according to an embodiment.

Referring to FIG. 17, the logic die 130 and the HBM 140 may be mounted on the substrate 110 and the bridge die 120 by performing a flip chip bonding process, for example. Each of the first connection members 131 connected to the logic die 130 may be bonded to the first bonding pad 114 of the substrate 110 and the second bonding pad 129 of the bridge die 120, so that the logic die 130 may be electrically connected to the substrate 110 and to the bridge die 120. Each of the second connection members 141 connected to the HBM 140 may be bonded to the first bonding pad 114 of the substrate 110 and the second bonding pad 129 of the bridge die 120, so that the HBM 140 may be electrically connected to the substrate 110 and the bridge die 120.

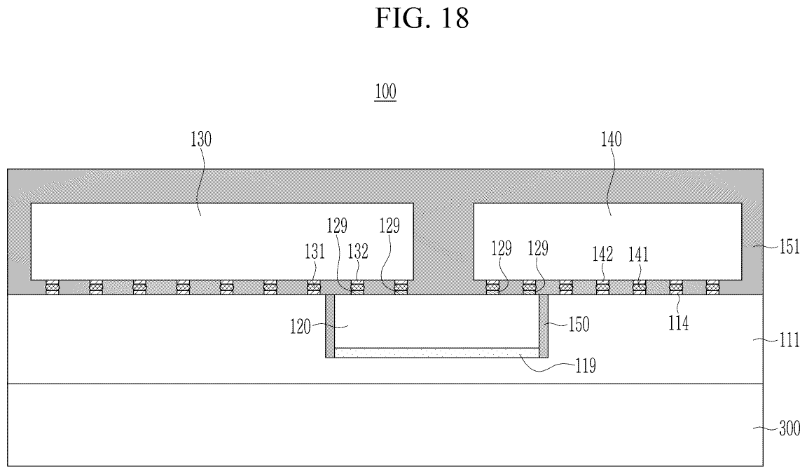

FIG. 18 illustrates a cross-sectional view of an operation of covering the logic die 130 and the HBM 140 with the second molding material 151 on the substrate 110, the bridge die 120, and the first molding material 150, according to an embodiment.

Referring to FIG. 18, the logic die 130 and the HBM 140 may be covered with the second molding material 151 on the bridge die 120 and the first molding material 150. In an embodiment, the process of molding with the second molding material 151 may include a compression molding and/or transfer molding process. In an embodiment, the second molding material 151 may include EMC.

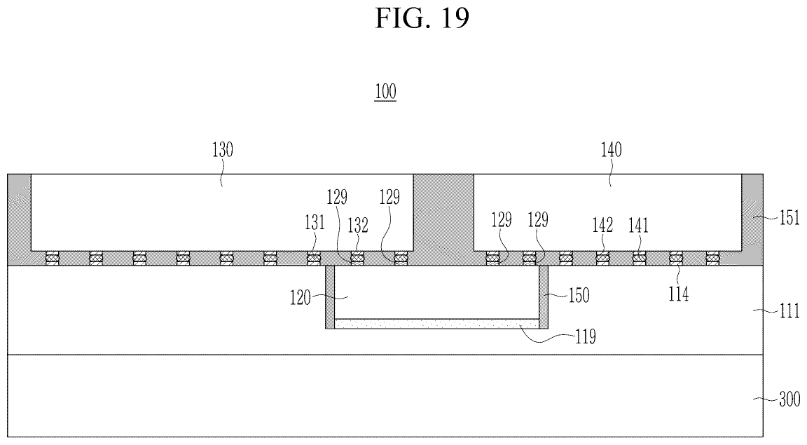

FIG. 19 illustrates a cross-sectional view of an operation of planarizing the second molding material 151, according to an embodiment.

Referring to FIG. 19, CMP may be performed to level the upper surface of the second molding material 151. The upper surface of the second molding material 151 may be planarized by applying the CMP process. After performing the CMP process, the upper surfaces of the logic die 130 and the HBM 140 may be exposed.

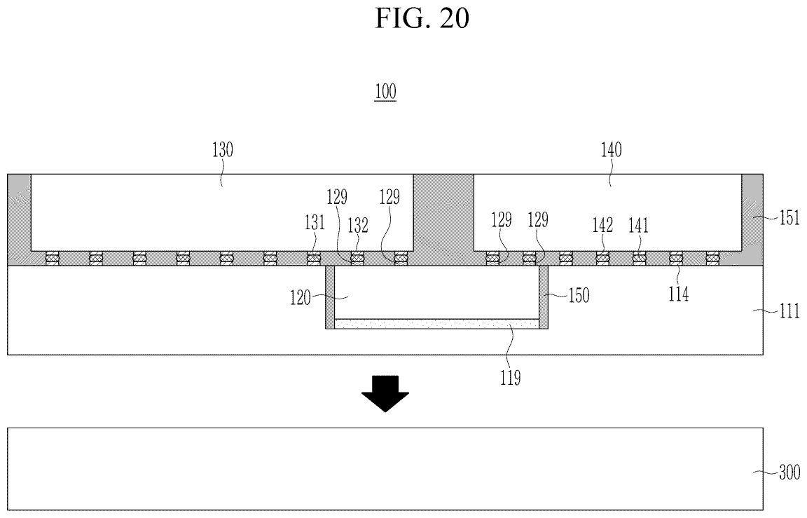

FIG. 20 illustrates a cross-sectional view of an operation of removing the carrier 300 from the substrate 110, according to an embodiment.

Referring to FIG. 20, the carrier 300 may be removed from the substrate 110.

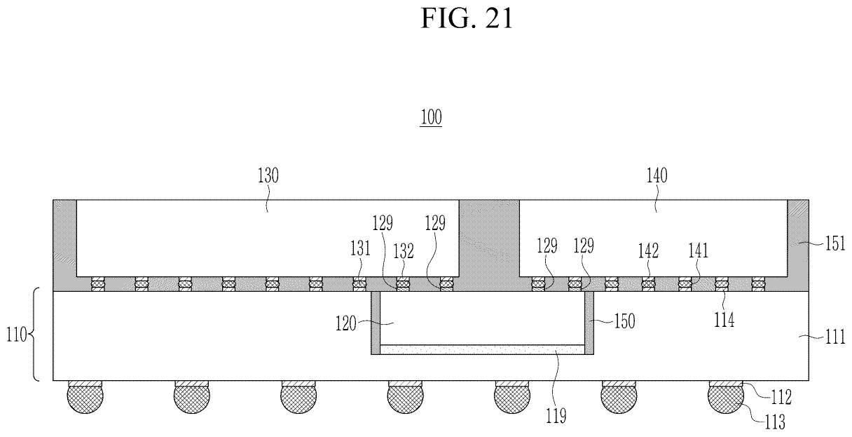

FIG. 21 illustrates a cross-sectional view of an operation of forming the connection pads 112 under the lower surface of the substrate 110 and forming the connection members 113 under the connection pads 112, according to an embodiment.

Referring to FIG. 21, the connection pads 112 may be formed under the lower surface of the substrate 110. In an embodiment, the connection pads 112 may be formed by performing a sputtering process, and/or by performing an electroplating process after forming a seed metal layer. Thereafter, the connection members 113 may be formed under the connection pads 112.

While the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A bridge chip, comprising:
a first side surface;
a second side surface opposite to the first side surface in a first horizontal direction;
a third side surface;
a fourth side surface opposite to the third side surface in a second horizontal direction intersecting the first horizontal direction;
a plurality of signal wires extending in a third horizontal direction between the first horizontal direction and the second horizontal direction, wherein first ends of the plurality of signal wires are disposed in a first line along the first side surface, and wherein second ends of the plurality of signal wires are disposed in a second line along the second side surface; and
one or more capacitor structures around the plurality of signal wires.

2. The bridge chip of claim 1, wherein the first horizontal direction and the second horizontal direction are orthogonal to each other, and
wherein the third horizontal direction is inclined at 45 degrees to the first horizontal direction.

3. The bridge chip of claim 1, wherein the bridge chip comprises a first area and a second area defined by dividing a plane of the bridge chip,
wherein the plurality of signal wires are disposed in the first area, and
wherein the plurality of signal wires are not disposed in the second area.

4. The bridge chip of claim 3, wherein the one or more capacitor structures are disposed in the second area.

5. The bridge chip of claim 1, wherein the bridge chip comprises a silicon bridge chip.

6. The bridge chip of claim 1, wherein the one or more capacitor structures comprise at least one of metal-insulator-metal (MIM) capacitors, deep trench capacitors (DTC), or integrated stack capacitors (ISC).

7. A semiconductor package, comprising:
a substrate comprising a cavity;
a bridge die disposed within the cavity, wherein the bridge die comprises a plurality of signal wires and one or more capacitor structures;
a first semiconductor die on the substrate and the bridge die; and
a second semiconductor die on the substrate and the bridge die,
wherein the second semiconductor die is spaced apart from the first semiconductor die in a first horizontal direction,
wherein the plurality of signal wires electrically couple the first semiconductor die with the second semiconductor die,
wherein the plurality of signal wires extend in a third horizontal direction between the first horizontal direction and a second horizontal direction orthogonal to the first horizontal direction, and
wherein the one or more capacitor structures are disposed around the plurality of signal wires.

8. The semiconductor package of claim 7, wherein at least one corner of a footprint of the first semiconductor die at least partially overlaps a footprint of the bridge die, and
wherein at least one corner of the footprint of the bridge die at least partially overlaps the footprint of the first semiconductor die.

9. The semiconductor package of claim 7, wherein at least one corner of a footprint of the second semiconductor die at least partially overlaps a footprint of the bridge die, and
wherein at least one corner of the footprint of the bridge die at least partially overlaps the footprint of the second semiconductor die.

10. The semiconductor package of claim 7, wherein the bridge die further comprises:
one or more through silicon vias disposed around the plurality of signal wires.

11. The semiconductor package of claim 10, wherein the one or more through silicon vias electrically couple at least one of the first semiconductor die and the second semiconductor die with the substrate.

12. The semiconductor package of claim 11, wherein each of the one or more through silicon vias is electrically coupled with a corresponding capacitor structure of the one or more capacitor structures.

13. The semiconductor package of claim 10, wherein the one or more through silicon vias are configured to transmit power.

14. The semiconductor package of claim 7, wherein the first semiconductor die comprises a logic die.

15. The semiconductor package of claim 7, wherein the second semiconductor die comprises a high bandwidth memory (HBM).

16. The semiconductor package of claim 7, wherein the substrate comprises at least one of a printed circuit board, a redistribution structure, or an interposer.

17. The semiconductor package of claim 7, further comprising:
an adhesive member between the bridge die and a bottom surface of the cavity.

18. The semiconductor package of claim 7, further comprising:
a plurality of connection members between the bridge die and a bottom surface of the cavity.

19. A semiconductor package, comprising:
a substrate comprising a cavity;
a bridge die disposed within the cavity, wherein the bridge die comprises a plurality of signal wires and one or more capacitor structures;
a first semiconductor die on the substrate and the bridge die;
a plurality of first connection members between the bridge die and the first semiconductor die;
a second semiconductor die on the substrate and the bridge die and spaced apart from the first semiconductor die in a first horizontal direction; and
a plurality of second connection members between the bridge die and the second semiconductor die,
wherein the plurality of first connection members are disposed in a first line along a side surface of the first semiconductor die facing the second semiconductor die,
wherein the plurality of second connection members are disposed in a second line along a side surface of the second semiconductor die facing the first semiconductor die;
wherein each of the plurality of signal wires electrically couples a corresponding first connection member of the plurality of first connection members with a corresponding second connection member of the plurality of second connection members,
wherein the plurality of signal wires extend in a third horizontal direction between the first horizontal direction and a second horizontal direction orthogonal to the first horizontal direction, and
wherein the one or more capacitor structures are disposed around the plurality of signal wires.

20. The semiconductor package of claim 19, wherein each of the plurality of signal wires comprises:
a first portion coupled with the corresponding first connection member and extending in the first horizontal direction;
a second portion extending in the third horizontal direction; and
a third portion coupled with the corresponding second connection member and extending in the first horizontal direction.
